(19) United States
(12) Patent Application Publication
(10) Pub. No.: US 2009/0072821 A1
(43) Pub. Date: Mar. 19, 2009

(54) CONTROL GATE

(75) Inventors: Kunihiro TAKAHASHI, Kanagawa (JP); Mario FUSE, Kanagawa (JP); Tsukasa MATSUDA, Kanagawa (JP); Shoji YAMAGUCHI, Kanagawa (JP); Yasunori KODA, Kanagawa (JP); Hiroyoshi INOUE, Kanagawa (JP)

Correspondence Address: OLIFF & BERRIDGE, PLC, P.O. BOX 320850, ALEXANDRIA, VA, 22320-4850, US

(73) Assignee: FUJI XEROX CO., LTD., Tokyo (JP)

(21) Appl. No.: 12/192,707

(22) Filed: Aug. 15, 2008

(30) Foreign Application Priority Data
Sep. 19, 2007 (JP) 2007-242489

(51) Int. Cl. G01R 33/12

(52) U.S. Cl. 324/234

(57) ABSTRACT

A control gate includes an exciting coil and a detecting coil. The exciting coil forms an alternating magnetic field in a passageway at an entrance to or an exit from an area where taking out or bringing in of an object is controlled. The detecting coil detects a change of the magnetic field when magnetic substance contained in the object generating a large Barkhausen effect causes magnetic inversion in the alternating magnetic field. The exciting coil is provided above the passageway and has a winding wire wound along a horizontal plane. The detecting coil is provided in a side part of the passageway and has a winding wire wound along a vertical plane which is parallel to a passing direction of the passageway.

### CROSS-REFERENCE TO RELATED APPLICATIONS

This application is based on and claims priority under 35 USC 119 from Japanese Patent Application No. 2007-242489 filed Sep. 19, 2007.

### BACKGROUND

1. Technical Field

The present invention relates to a control gate for controlling a carried object which is prohibited from being taken out or brought into a specified area, by detecting a change of a magnetic field due to magnetic inversion of magnetic substance generating a large Barkhausen effect.

2. Related Art

As a control gate for detecting passage of the carried object which is prohibited from being taken out or brought in, and issuing a warning, utilizing magnetic substance which generates a large Barkhausen effect have been known.

### SUMMARY

According to an aspect of the invention, a control gate includes an exciting coil and a detecting coil. The exciting coil forms an alternating magnetic field in a passageway at an entrance to or an exit from an area where taking out or bringing in of an object is controlled. The detecting coil detects a change of the magnetic field when magnetic substance contained in the object generating a large Barkhausen effect causes magnetic inversion in the alternating magnetic field. The exciting coil is provided above the passageway and has a winding wire wound along a horizontal plane. The detecting coil is provided in a side part of the passageway and has a winding wire wound along a vertical plane which is parallel to a passing direction of the passageway.

### BRIEF DESCRIPTION OF THE DRAWINGS

Exemplary embodiments of the present invention will be described in detail based on the following figures, wherein:

FIG. 1 is a schematic perspective view of a control gate in a first exemplary embodiment according to the invention;

FIG. 2 is a schematic perspective view of a control gate in a second exemplary embodiment according to the invention;

FIG. 3 is a schematic perspective view of a control gate in a third exemplary embodiment according to the invention;

FIG. 4 is a schematic perspective view of a control gate in a fourth exemplary embodiment according to the invention;

FIG. 5 is a schematic perspective view of a control gate in a fifth exemplary embodiment according to the invention;

FIG. 6 is a schematic perspective view of a control gate in a sixth exemplary embodiment according to the invention; and

FIG. 7A and FIG. 7B are schematic views showing examples of a shape of a winding wire of a detecting coil which can be used in the control gate according to the invention.

### DETAILED DESCRIPTION

Now, exemplary embodiments of the invention of this application will be described referring to the drawings.

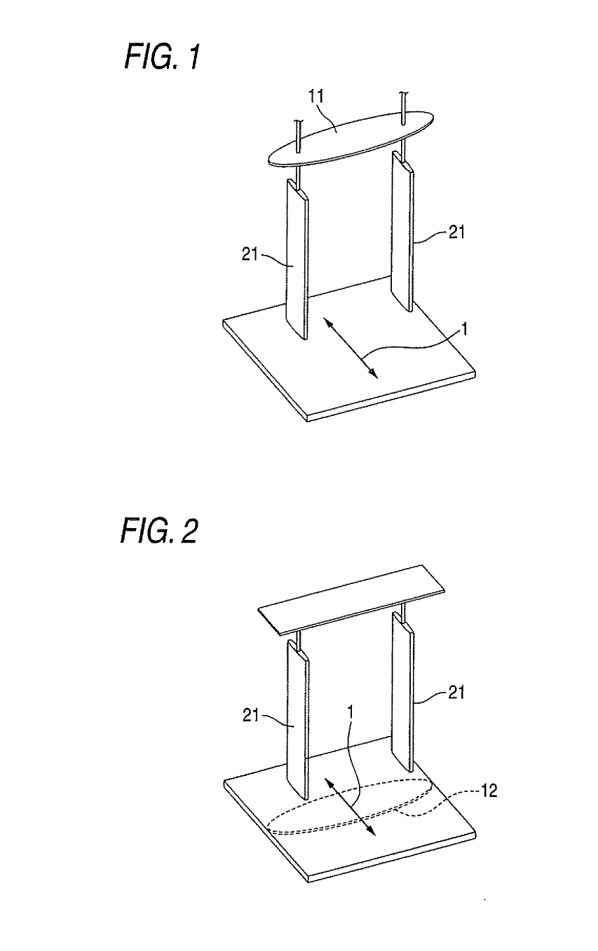

A control gate as shown in FIG. 1 is a gate for detecting a confidential document contained in the carried object, and by installing the control gate at an entrance or an exit of an area where confidentiality must be ensured, the confidential document is prevented from being taken out or brought in illegally or by mistake.

In the area where the confidentiality must be ensured, the confidential matter is stored in a form of a document or electronic data, and the document is made by a printer or a copying machine. On this occasion, the confidential document is made by using paper which contains magnetic substance generating a large Barkhausen effect. This paper may be such that the magnetic substance generating the large Barkhausen effect is embedded in the paper in a manner scattered in random overall and cannot be easily removed. As the magnetic substance, a fine Fe—Co amorphous metallic wire (having a diameter of several ten micron and a length of 1 mm or more), for example, can be used. Besides, soft magnetic substance generating the large Barkhausen effect can be also used.

FIG. 1 is a schematic view showing a structure of the control gate which is provided at the entrance or exit of the aforesaid control area.

This control gate is provided on a passageway 1 at the entrance to or the exit from the control area where the confidential document is prohibited from being taken out or brought in. The control gate includes an exciting coil 11 which forms an alternating magnetic field on the passageway 1, and detecting coils 21 which detect a change of a magnetic field, when the magnetic substance generating the large Barkhausen effect causes magnetic inversion in the magnetic field which is formed by the exiting coil. The exciting coil 11 and the detecting coils 21 are respectively contained in separate containing cases. The exciting coil 11 is suspended from a ceiling above the passageway 1 to enter into the control area. The detecting coils 21 are suspended from the ceiling in a state respectively contained in the containing cases at both sides of the passageway.

The aforesaid exciting coil 11 has a winding wire which is wound along a horizontal plane above the passageway 1, and when an alternating voltage is applied to the exciting coil 11 from a power source (not shown), the alternating magnetic field is formed in the passageway 1. The winding wire of this exciting coil 11 has such a shape that it has the major axis in a width direction of the passageway, and forms the magnetic field which is larger than a coercive force of the magnetic substance passing through the passageway, across an entire width of the passageway. Moreover, the exciting coil 11 forms the magnetic field in a sufficient range to detect the change of the magnetic field due to the magnetic inversion, also in a passing direction of the passageway.

Therefore, the shape and size of the winding wire which is wound can be determined depending on a size of the entrance or exit of the area where the carried object is controlled, and a size of the magnetic substance contained in the confidential document, and so on. For example, the size of the winding wire can be about 1.0 to 2.0 m in a direction of the major axis, and about 0.9 m in a direction of the minor axis.

The aforesaid detecting coils 21 are wound along vertical planes which are parallel to the passing direction of the passageway 1, and respectively suspended from the ceiling and held at both sides of the passageway 1, in a state contained in the containing cases having a flat shape. Positions where these detecting coils 21 are to be held are set to be as close as possible to a passing area along both end edges of the passageway in the width direction, directly below the exciting coil 11. These detecting coils 21 are provided for the purpose of detecting an inductive current when the magnetic field changes due to the magnetic inversion which occurs in the magnetic substance passing through the alternating magnetic field formed by the exciting coil 11. A signal of this detection is inputted to signal processing unit (not shown).

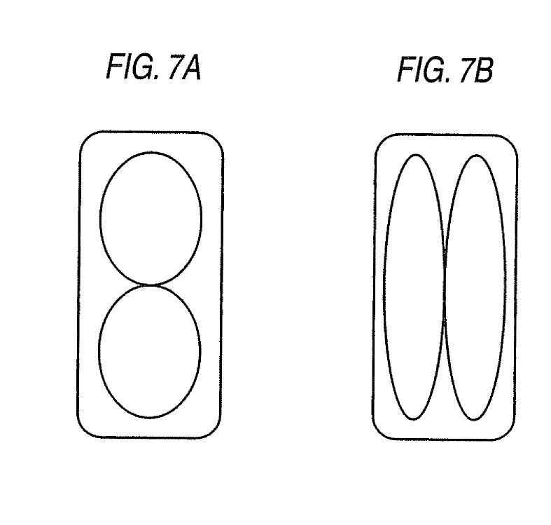

The winding wire of each of the detecting coils 21 has such a size and winding number as capable of detecting the magnetic substance which is passing, and a width of the detecting coil 21 in the passing direction can be about 0.7 to 0.9 m, for example. Moreover, the size in the vertical direction is determined so that the magnetic inversion of the magnetic substance which is contained in the object carried by a passenger can be detected. Further, the detecting coil 21 is wound in a shape of the number eight as shown in FIG. 7A, or in a shape of the infinity symbol as shown in FIG. 7B. In this manner, concerning the change of the magnetic field formed in a wide range such as the alternating magnetic field formed by the exciting coil 11, the electric current is induced to opposite directions by an almost half of the detecting coil 21 and by the other half, whereby a level of the voltage which is induced to the detecting coil 21 by the alternating magnetic field can be lowered.

In the control gate as described above, the alternating magnetic field is formed in the passageway below this exciting coil, by the exciting coil 11 which is provided above the passageway. When the carried object which contains the magnetic substance generating the large Barkhausen effect is brought into this passageway, a rapid magnetic inversion occurs periodically in the magnetic substance by the alternating magnetic field, and the magnetic field changes. The inductive current in a form of periodical pulse is generated in the detecting coils 21 due to this change of the magnetic field. The signal processing unit judges the output signal according to its periodicity or so, and can detect passage of an object article to be detected containing the magnetic substance. On this occasion, the plane where the winding wire of the exciting coil 11 is wound is at a right angle with respect to the planes where the winding wires of the detecting coils 21 are wound, and hence, the current which is induced to the detecting coils 21 by the alternating magnetic field formed by the exciting coil 11 is decreased, as compared with the case where the exciting coil and the detecting coils are wound along the same vertical plane, or the case where they are wound along the vertical planes opposed to each other. On the other hand, because the magnetic inversion of the magnetic substance occurs within a narrow range at a position near the detecting coils 21, it is possible to detect the change of the magnetic field due to this magnetic inversion at a high level by the detecting coils 21. Moreover, even though the detecting coils 21 are wound in a shape of the number eight or in a shape of the infinity symbol, the change of the magnetic field due to the magnetic inversion which has occurred near the detecting coils hardly induces the current so as to be compensated in the detecting coils, but can be detected at the high level.

Further, because the exciting coil 11 is suspended from the ceiling, the height of the exciting coil can be easily adjusted, and it is possible to adjust the height, considering distribution of intensity of the alternating magnetic field which is formed in the passageway.

FIG. 2 is a schematic perspective view showing the control gate in a second exemplary embodiment according to the invention.

In this control gate, although the detecting coils 21 are suspended from the ceiling in the same manner as in the control gate as shown in FIG. 1, the exciting coil 12 is provided under a floor surface directly below the detecting coils 21 which are suspended. The structure of the exciting coil 12 and the detecting coil 21 are the same as in the control gate as shown in FIG. 1.

In the control gate as described above, the exciting coil 12 is arranged at a position near the object carried by a passenger, and hence, an effective alternating magnetic field can be formed in the passageway, even in case where only a small amount of electric power is supplied to the exciting coil 12. Moreover, the exciting coil 12 will not hinder passage of the passenger.

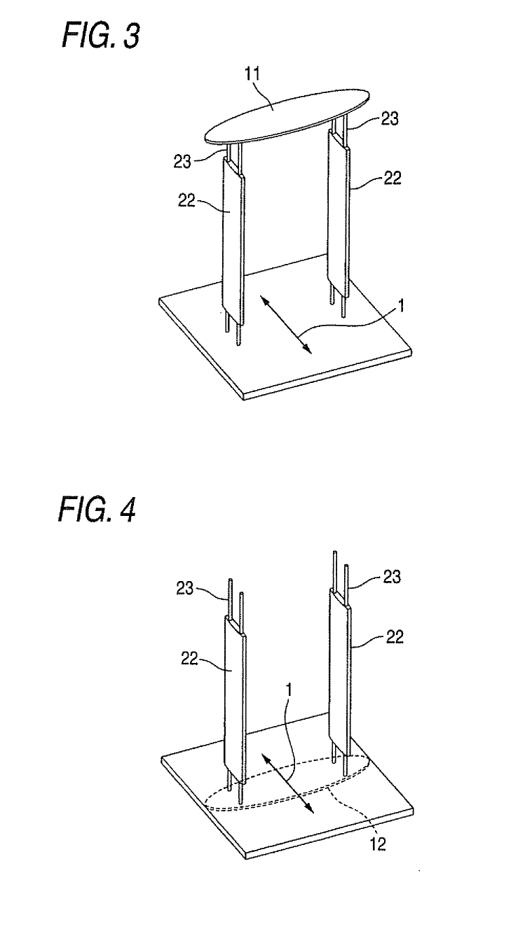

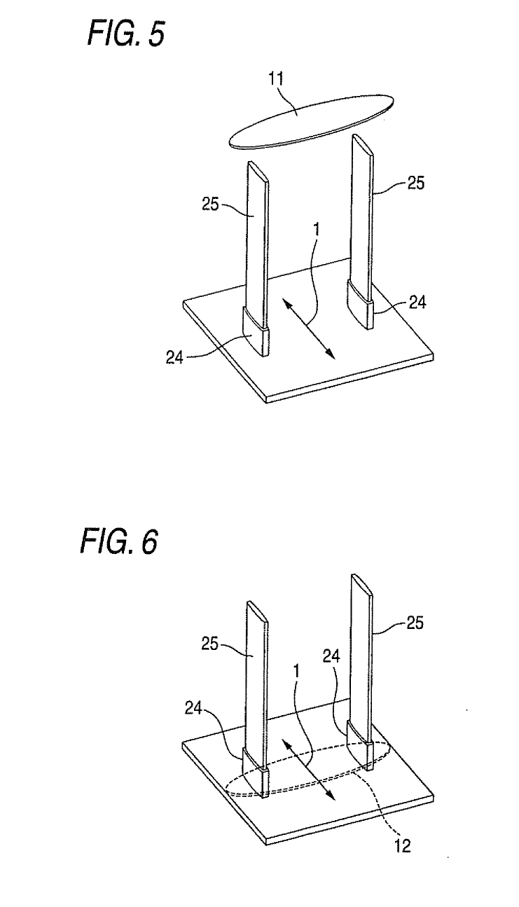

On the other hand, the detecting coils 21 are suspended from the ceiling in the control gates which are shown in FIGS. 1 and 2. However, it is also possible to set up a plurality of supporting posts 23 from the floor surface, as shown in FIGS. 3 and 4, thereby to support the detecting coils 22 by these supporting posts. Moreover, as shown in FIG. 3, it is possible to support the exciting coil 11 too in upper parts of these supporting posts 23. On the other hand, as shown in FIGS. 5 and 6, it is also possible to provide supporting bases 24 on the floor surface so that the detecting coils 25 which are contained in the containing cases may be arranged on these supporting bases. Further, various other supporting unit can be selected, provided that the detecting coils can be supported at determined positions along side faces of the passageway. On the other hand, the exciting coil can be selectively suspended from the ceiling or arranged under the floor surface, irrespective of the manner of supporting the detecting coils.

The above described control gate can be used as the gate for judging whether the passenger can pass the gate or not, by checking the detecting signal of the detecting coil against personal information in a card or the like which has been inputted by the passenger, or for judging whether the passenger can pass the gate or not, by referring to conditions of passage, such as time. Moreover, it is possible to employ a unit for conducting opening and closing motions of a door or the like according to the results of these judgments, or a unit for announcing the results of the judgments to a controlling person, such as giving a warning, lighting a lamp, issuing an alarm, sending an E-mail to the controlling person, and so on.

Further, the invention of this application is not limited to the above described exemplary embodiments, but the description in the scope of claims for patent can be realized in various other exemplary embodiments. For example, appropriate shapes and winding numbers of the exciting coil and the detecting coils can be selected depending on the position where the control gate is used, the object article to be detected, and so on. Moreover, the position where the control gate is provided is not limited to the position near the entrance or exit of the area where the carried object is controlled, but the gate may be provided in a border part between the control areas which are classified according to confidential level or so. Further, it is possible to extensively control a plurality of the control gates by providing a server for centralizing the reference data and the obtained information.

Still further, the object to be detected is not limited to the confidential document, but may be commodities or furnishings, and so on. The manner of adding the magnetic substance generating the large Barkhausen effect can be also selected from various manners, such as attaching a tag, and so on.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A control gate comprising:
an exciting coil that forms an alternating magnetic field in a passageway at an entrance to or an exit from an area where taking out or bringing in of an object is controlled, and
a detecting coil that detects a change of the magnetic field when magnetic substance contained in the object generating a large Barkhausen effect causes magnetic inversion in the alternating magnetic field,
wherein the exciting coil is provided above the passageway,
the exciting coil has a winding wire wound along a horizontal plane,
the detecting coil is provided in a side part of the passageway, and
the detecting coil has a winding wire wound along a vertical plane which is parallel to a passing direction of the passageway.

2. The control gate according to claim 1,
wherein the exciting coil is held on a ceiling which is above the passageway.

3. The control gate according to claim 1,
wherein the detecting coil is suspended from a ceiling above the passageway.

4. A control gate comprising:
an exciting coil that forms an alternating magnetic field in a passageway at an entrance to or an exit from an area where taking out or bringing in of an object is controlled, and
a detecting coil that detects a change of the magnetic field when magnetic substance contained in the object generating a large Barkhausen effect has caused magnetic inversion in said alternating magnetic field,
wherein the exciting coil is provided under a floor surface of the passageway,
the exciting coil has a winding wire wound along the floor surface,
the detecting coil is provided in a side part of the passageway,
the detecting coil has a winding wire wound along a vertical plane which is parallel to a passing direction of the passageway.

5. The control gate according to claim 4,
wherein the detecting coil is suspended from a ceiling above the passageway.

6. The control gate according to claim 1,
wherein the winding wire of the detecting coil is wound in a shape of one of the number eight or the infinity symbol, along a vertical plane which is substantially parallel to the passing direction of the passageway.
